(19) United States
(12) Patent Application Publication
(10) Pub. No.: US 2010/0155799 A1
(43) Pub. Date: Jun. 24, 2010

(54) SEMICONDUCTOR DEVICE AND METHOD FOR MANUFACTURING THE SAME

(75) Inventor: Shigeyuki YOKOYAMA, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 12/638,066

(22) Filed: Dec. 15, 2009

(30) Foreign Application Priority Data
Dec. 22, 2008 (JP) 2008-325461

(51) Int. Cl. H01L 27/108; H01L 27/088; H01L 21/8242

(52) U.S. Cl. 257/296; 257/392; 438/239; 257/334; 257/E21.646; 257/E27.084; 257/E27.06

(57) ABSTRACT

A first MOS transistor includes, as a first impurity region, a pair of first source/drain regions including first portions formed in a semiconductor substrate and second portions formed so as to project upward from the first portions. A second MOS transistor includes a pair of second source/drain regions including second impurity regions formed in the semiconductor substrate, third impurity regions located in contact with the second impurity regions so as to project upward from the semiconductor substrate, and fourth impurity regions located on the third impurity regions. The concentration of impurities in the third impurity regions is lower than that of impurities in the fourth impurity regions. The concentration of impurities in the first impurity regions is lower than that of impurities in the second impurity regions. The first, the second, the third and the fourth impurity regions are same conductivity type.

This application is based upon and claims the benefit of priority from Japanese Patent Application No. 2008-325461, filed on Dec. 22, 2008, the disclosure of which is incorporated herein in its entirety by reference.

### BACKGROUND OF THE INVENTION

1. Field of the Invention

The present invention relates to a semiconductor device and a method for manufacturing the semiconductor device.

2. Description of the Related Art

With the increasing miniaturization of MOS transistors used in semiconductor devices, it has been more and more important to inhibit a possible short channel effect. As means for inhibiting a possible short channel effect, a technique is known which forms a silicon layer (raised silicon layer) on an active region of a MOS transistor by a selective epitaxial growth method so that the silicon layers can be used as source/drain regions. This technique is disclosed in Japanese Patent Laid-Open No. 5-182981.

FIG. 14 is a sectional view of a related MOS transistor in which a raised silicon layer is formed on an active region to inhibit a possible short channel effect. In the MOS transistor, gate electrode 205 is formed on a semiconductor substrate 201 via gate insulating film 205a. Reference numeral 203 denotes an isolation region. Impurity regions 208a of a low concentration are formed in semiconductor substrate 201 so as to function as a part of source/drain regions. Impurity regions 209 are raised silicon regions formed without introduction of impurities. Impurity regions 209b containing high-density impurities are formed close to the raised silicon layers in order to reduce electric resistance.

Furthermore, known MOS transistors which, even when miniaturized and densely configured, appropriately inhibit a possible short channel effect include a MOS transistor comprising a trench gate electrode and a MOS transistor comprising channel regions formed on respective side surface portions of a trench formed in a semiconductor substrate. Japanese Patent Laid-Open Nos. 2006-339476 and 2007-158269 disclose such MOS transistors.

Furthermore, in order to allow a demand for improvement of the performance of semiconductor devices to be met, MOS transistors with different characteristics are mixedly formed on one semiconductor chip.

For example, in a DRAM (Dynamic Random Access Memory) element, MOS transistors with a possible leakage current inhibited in an off state are densely arranged in a memory cell region. Furthermore, MOS transistors with a large drain current flowing therethrough in an on state are arranged in the regions (peripheral circuit regions) other than memory cells. This enables formation of a high-performance DRAM with appropriate information holding characteristics (refresh characteristics) and high-speed operation characteristics.

### SUMMARY OF THE INVENTION

In one embodiment, there is provided a semiconductor device comprising a semiconductor substrate, a first circuit region and a second circuit region,

wherein the first circuit region comprises:

a first MOS transistor comprising, as first impurity regions, a pair of first source/drain regions including first portions formed in the semiconductor substrate and second portions formed on the first portions so as to project from the semiconductor substrate,

the second circuit region comprises:

a second MOS transistor comprising a pair of second source/drain regions including second impurity regions formed in the semiconductor substrate, third impurity regions formed so as to be in contact with the second impurity regions and to extend upward from the semiconductor substrate, and fourth impurity regions formed on the third impurity regions,

the first, the second, the third and the fourth impurity regions are same conductivity type,

the amount of impurity in the third impurity regions is smaller than the amount of impurity in the fourth impurity regions, and the amount of impurity in the first impurity regions is smaller than the amount of impurity in the second impurity regions.

In another embodiment, there is provided a semiconductor device comprising:

a semiconductor substrate;

a first circuit region comprising a first MOS transistor including a pair of first source/drain regions with first impurity regions; and

a second circuit region comprising a second MOS transistor including a pair of second source/drain regions, the second source/drain regions including second impurity regions as a bottom layer, third impurity regions disposed on the second impurity regions, and fourth impurity regions disposed on the third impurity regions,

wherein the first impurity regions comprise first portions formed immediately beneath a surface of the semiconductor substrate and second portions formed on the first portions so as to project from the surface of the semiconductor substrate,

the second impurity regions are formed in the semiconductor substrate,

the third and fourth impurity regions are formed so as to project from the surface of the semiconductor substrate,

the first, the second, the third and the fourth impurity regions are same conductivity type,

the amount of impurity in the third impurity regions is smaller than the amount of impurity in the fourth impurity regions,

the amount of impurity in the first impurity regions is smaller than the amount of impurity in the second impurity regions, and

a threshold voltage of the first MOS transistor is larger than a threshold voltage of the second MOS transistor.

In another embodiment, there is provided a method for manufacturing a semiconductor device, the method comprising:

preparing a semiconductor substrate comprising a first active region and a second active region;

forming gate insulating films and gate electrodes in the first and second active regions, respectively;

implanting first conductive type impurity into portions of the second active region arranged opposite each other across the gate electrode in the semiconductor substrate to form a pair of second impurity regions;

forming semiconductor layers on portions of the first active region arranged opposite each other across the gate electrode in the semiconductor substrate and on the second impurity regions in the second active region, the semiconductor layers projecting upward from the semiconductor substrate;

implanting first conductive type impurity into lower portions of the semiconductor layers on the second impurity regions to form a pair of third impurity regions in contact with the second impurity regions;

implanting first conductive type impurity into upper portions of the semiconductor layers on the second impurity regions to form a pair of fourth impurity regions in contact with the third impurity regions, whereby forming a second MOS transistor, an impurity concentration of the third impurity regions being smaller than an impurity concentration of the fourth impurity regions; and

implanting first conductive type impurity into portions of the first active region arranged opposite each other across the gate electrode in the semiconductor substrate and into the semiconductor layers on the portions of the first active region to form a pair of first impurity regions, whereby forming a first MOS transistor, an impurity concentration of the first impurity regions being smaller than an impurity concentration of the second impurity regions.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a top view illustrating a semiconductor device according to an exemplary embodiment;

FIG. 2 is a top view illustrating the semiconductor device according to the exemplary embodiment;

FIGS. 3A and 3B are sectional views illustrating the semiconductor device according the exemplary embodiment;

FIGS. 4A and 4B are diagrams illustrating a step of a method for manufacturing a semiconductor device according to the exemplary embodiment;

FIGS. 5A and 5B are diagrams illustrating a step of the method for manufacturing the semiconductor device according to the exemplary embodiment;

FIGS. 6A and 6B are diagrams illustrating a step of the method for manufacturing the semiconductor device according to the exemplary embodiment;

FIGS. 7A and 7B are diagrams illustrating a step of the method for manufacturing the semiconductor device according to the exemplary embodiment;

FIGS. 8A and 8B are diagrams illustrating a step of the method for manufacturing the semiconductor device according to the exemplary embodiment;

FIGS. 9A and 9B are diagrams illustrating a step of the method for manufacturing the semiconductor device according to the exemplary embodiment;

FIGS. 10A and 10B are diagrams illustrating a step of the method for manufacturing the semiconductor device according to the exemplary embodiment;

FIGS. 11A and 11B are diagrams illustrating a step of the method for manufacturing the semiconductor device according to the exemplary embodiment;

FIGS. 12A and 12B are diagrams illustrating a step of the method for manufacturing the semiconductor device according to the exemplary embodiment;

FIG. 13 is a diagram illustrating a step of the method for manufacturing the semiconductor device according to the exemplary embodiment;

FIG. 14 is a sectional view illustrating a related semiconductor device;

FIGS. 15A and 15B are diagrams illustrating the operational state of a first MOS transistor; and

FIGS. 16A and 16B are diagrams a diagram illustrating the operational state of the first MOS transistor.

### DESCRIPTION OF SYMBOLS

In the drawings, numerals have the following meanings. 1: semiconductor substrate, 2: trench pattern, 3: isolation region, 4: first interlayer insulating film, 4A, 6B, 10A, 10B, 21A, 21B, 22B: contact plugs, 5: gate electrode, 5a: gate insulating film, 5b: side wall, 5c: insulating film, 6: bit line, 6B: first wiring layer, 7: word line, 8: silicon layer, 8a: first portion, 8S: source region, 8D: drain region, 10: second interlayer insulating film, 21: third interlayer insulating film, 22: fourth interlayer insulating film, 24: capacitor element, 24a: lower electrode, 24b: upper electrode, 30: fifth interlayer insulating film, 31: wiring layer, 32: surface protection film, 35: side portion, 105: gate electrode, 108a: second impurity region, 108S: source region, 108D: drain region, 109: silicon layer, 109a: third impurity region, 109b: fourth impurity region, 201: semiconductor substrate, 203: isolation region, 205: gate electrode, 205d: gate insulating film, 205a, 205b, 205c: substrate contact sections, 208a, 209, 209b: impurity regions, K: active region, Tr1: MOS transistor, Tr2: planar MOS transistor.

### DETAILED DESCRIPTION OF THE PREFERRED EMBODIMENTS

The present invention will be described with reference to exemplary embodiments illustrated below. The exemplary embodiments described below are applied to a DRAM element corresponding to a specific example of a semiconductor device comprising a region (first circuit region) in which MOS transistors with a possible leakage current inhibited in an off state are arranged and a region (second circuit region) in which MOS transistors with a large drain current flowing therethrough in an on state are arranged. The exemplary embodiments described below are for the description of the present invention. The scope of the present invention includes variations of the exemplary embodiments described below. The present invention is not limited to the exemplary embodiments described below.

In the exemplary embodiments described below, the amount of impurities in first impurity regions to fifth impurity regions refers to the content of impurities in each of the impurity regions in atoms/cm² unit.

### First Exemplary Embodiment

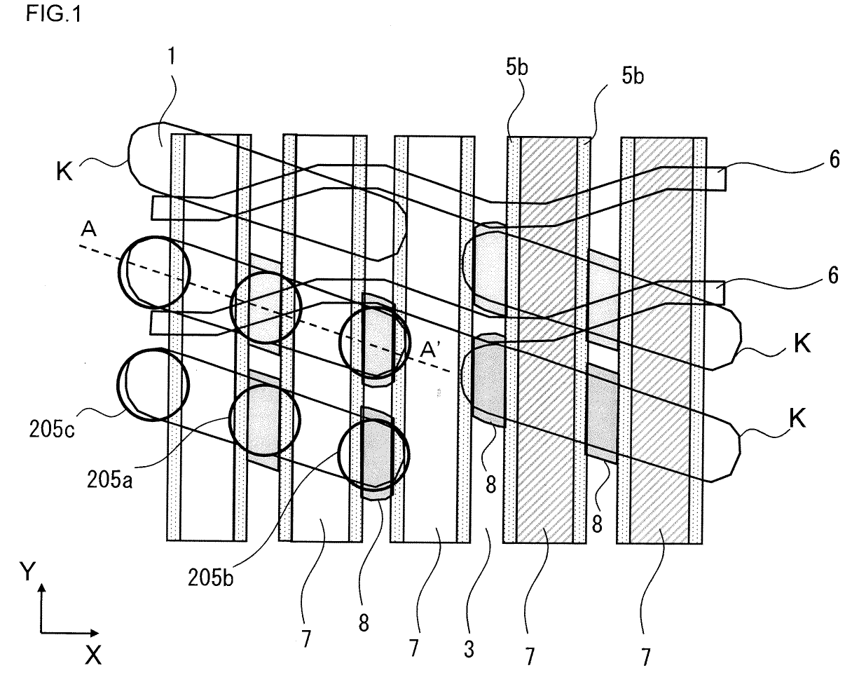

FIG. 1 is a schematic diagram showing the planar structure of a memory cell section of a DRAM element corresponding to a semiconductor device according to the exemplary embodiment. The memory cell section corresponds to a region (first circuit region) in which first MOS transistors with a possible leakage current inhibited in an off state are arranged.

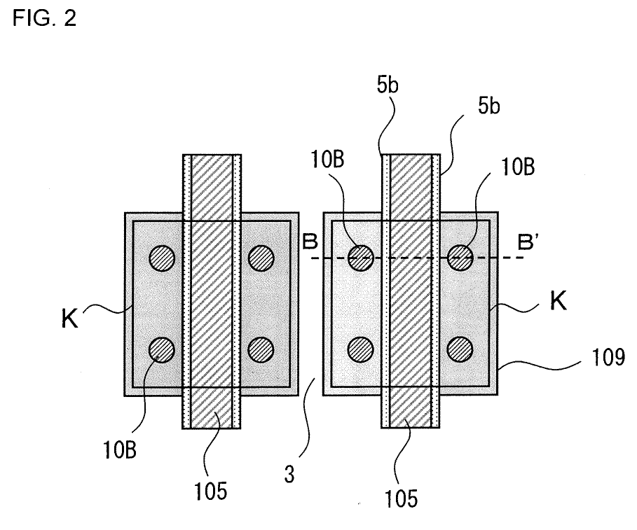

FIG. 2 is a schematic diagram showing the planar structure of essential components of a peripheral circuit section of the DRAM element corresponding to the semiconductor device according to the exemplary embodiment. The peripheral circuit section corresponds to a region (second circuit region) in which second MOS transistors with a large drain current flowing therethrough in an on state are arranged.

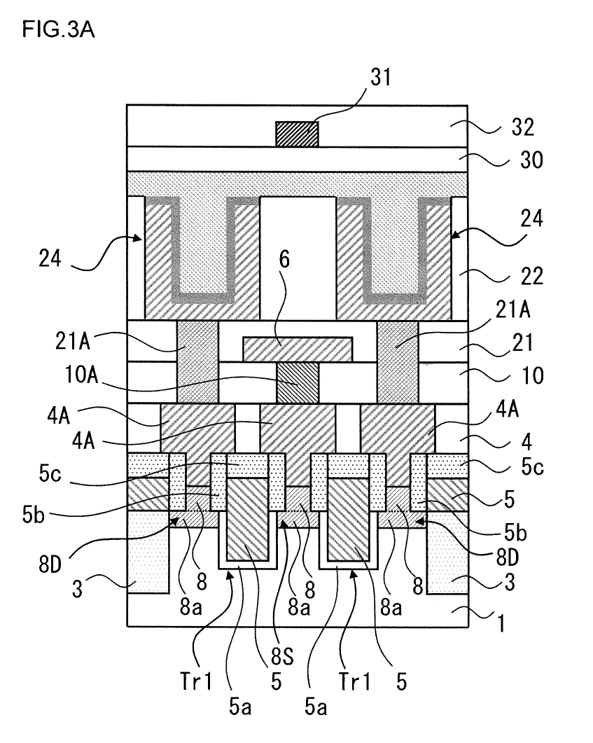

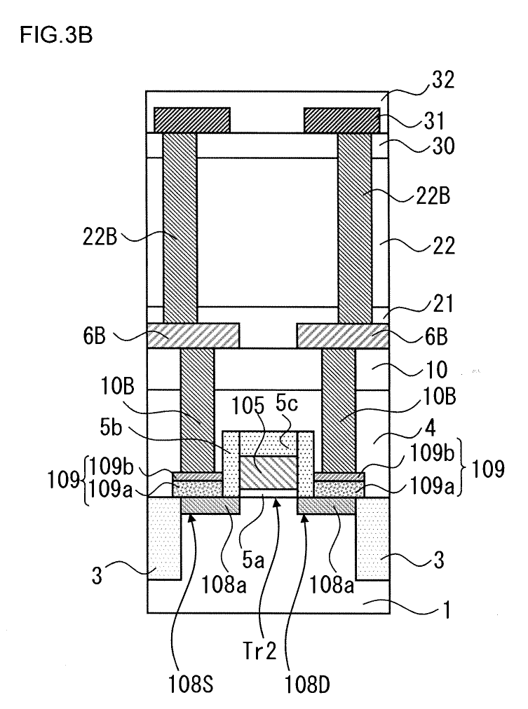

FIG. 3A is a schematic sectional view corresponding to line A-A′ in FIG. 1 (memory cell section), and FIG. 3B is a schematic sectional view corresponding to line B-B′ in FIG. 2 (peripheral circuit section). These figures are for description of the configuration of the semiconductor device. The sizes and the like of the illustrated components are not consistent with the dimensional relationships in the actual semiconductor device.

The DRAM element corresponding to the semiconductor device according to the exemplary embodiment roughly comprises the memory cell section and the peripheral circuit section. The memory cell section and the peripheral circuit section may be arranged in a desired manner according to the application of the semiconductor device. For example, the peripheral circuit section may be located so as to surround the memory cell section.

First, the memory cell section will be described with reference to FIGS. 1 and 3A. The memory cell section comprises a plurality of memory cells. As shown in FIG. 3A, each of the memory cells roughly comprises first MOS transistors Tr1 for memory cells and capacitance sections (capacitor elements) 24 each connected to the first MOS transistor Tr1 via contact plugs 4A and 21A. In FIG. 3A, first source region 8S is shared by two first MOS transistors Tr1, and the two memory cells are shown.

In FIGS. 1 and 3A, semiconductor substrate 1 is a semiconductor containing a predetermined concentration of P-type impurities. Semiconductor substrate 1 is formed of, for example, silicon. Isolation regions 3 are formed in semiconductor substrate 1. Each of isolation regions 3 is formed by embedding an insulating film such as a silicon oxide film (SiO₂) or the like in regions of the surface of semiconductor substrate 1 which are different from active regions K using the Shallow Trench Isolation (STI) technique. Isolation region 3 is separated and insulated from adjacent active regions K. In the exemplary embodiment, the present invention is applied to a cell structure in which 2-bit memory cells are arranged in one active region K.

In the exemplary embodiment, as shown in the planar structure in FIG. 1, a plurality of elongate reed-shaped active regions K are formed at predetermined intervals so as to extend aligningly obliquely downward rightward. Impurity regions are arranged at the opposite ends and in the central portion of each active region K. In the exemplary embodiment, first source region 8S is formed in the central portion of each active region K. First drain regions 8D are formed at the opposite ends of each active region K. Substrate contact sections 205a, 205b, and 205c are formed so as to line immediately on first source region 8S and first drain regions 8D, respectively.

The arrangement of planar active regions K as shown in FIG. 1 is inherent in the exemplary embodiment. The shape and aligning direction of active regions K are not particularly limited. The shape of active regions K shown in FIG. 1 has only to be applicable to other common transistors and is not limited to the one according to the exemplary embodiment. Furthermore, the first source region is interchangeable with the first drain region.

Bit lines 6 shaped like broken lines are extended in the lateral direction (X) of FIG. 1. A plurality of bit lines 6 are arranged at predetermined intervals in the lengthwise direction (Y) of FIG. 1. Furthermore, linear word lines 7 are arranged so as to extend in lengthwise direction (Y) of FIG. 1. A plurality of word lines 7 are arranged at predetermined intervals in lateral direction (X) of FIG. 1. Each of word lines 7 contains gate electrode 5 shown in FIG. 3A, in a portion thereof in which word line 7 crosses active region K.

As shown in the sectional structure in FIG. 3A, first source region 8S and first drain regions 8D are separately formed in active region K defined by isolation regions 3 in semiconductor substrate 1. Trench gate electrode 5 is formed between first source region 8S and each first drain region 8D.

Gate electrode 5 is formed of a multilayer film of a polycrystalline silicon film and a metal film so as to project upward from semiconductor substrate 1. The polycrystalline silicon film can be formed by depositing an appropriate material by a CVD (Chemical Vapor Deposition) method so that the film contains impurities such as phosphorous. Alternatively, the polycrystalline silicon film may be formed by using an ion implantation method to dope N- or P-type impurities into a polycrystalline silicon film formed during deposition so as not to contain any impurities. The metal film may be high-melting-point metal such as tungsten (W), tungsten nitride (WN), tungsten silicide (WSi), or the like.

Furthermore, as shown in FIG. 3A, gate insulating film 5a is formed between gate electrode 5 and semiconductor substrate 1. Side walls 5b composed of an insulating film such as silicon nitride (Si₃N₄) are formed on side surfaces of gate electrode 5. Insulating film 5c such as silicon nitride is also formed on gate electrode 5.

Each of first source region 8S and first drain regions 8D comprises first impurity regions including impurity regions 8a (corresponding to first portions) formed in a surface portion of semiconductor substrate 1 and silicon layers 8 (corresponding to second portions) formed in contact with impurity regions 8a and in which impurities are ion-implanted. That is, the first impurity regions are formed inside silicon layers 8 and diffuse to the surface portion of semiconductor substrate 1; the first impurity regions are formed integrally inside silicon layers 8 and in the surface portion of semiconductor substrate 1. Silicon layers 8 are formed by a selective epitaxial growth method. For example, as N-type impurities, phosphorous is doped into the first impurity regions.

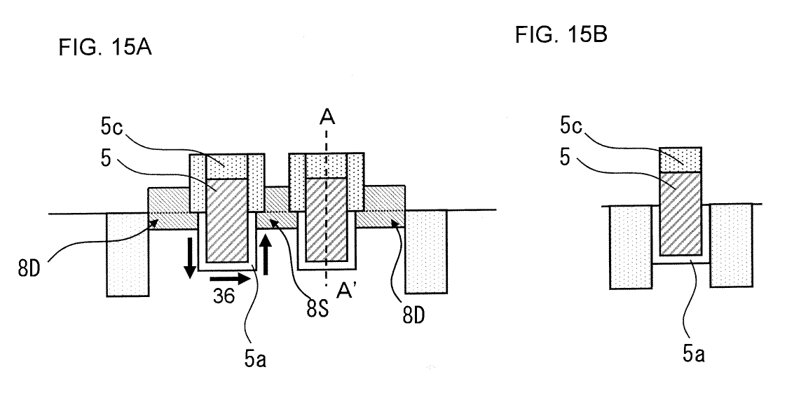

FIG. 15A is a sectional view illustrating the operational state of first MOS transistor Tr1. FIG. 15B is a sectional view in an A-A′ direction in FIG. 15A. As shown in FIG. 15, in the MOS transistor, a channel region is formed in the direction of arrow 36 along a gate insulating film.

Furthermore, as shown in FIG. 3A, first interlayer insulating film 4 is formed on semiconductor substrate 1. Substrate contact plugs 4A are formed so as to penetrate first interlayer insulating film 4. Substrate contact plugs 4A are arranged at the positions of respective substrate contact sections 205c, 205a, and 205b shown in FIG. 1. Each substrate contact plug 4A is formed so as to connect to silicon layer 8 formed as a part of each of first source region 8S and first drain regions 8D. Substrate contact plug 4A is formed of a polycrystalline silicon layer containing, for example, phosphorous.

Moreover, second interlayer insulating film 10 is stacked on first interlayer insulating film 4. Bit line contact plug 10A connected to substrate contact plug 4A is formed in second interlayer insulating film 10. Bit line contact plug 10A is formed by stacking tungsten (W) or the like on a barrier film (TiN/Ti) comprising a stack film of titanium nitride (TiN) and titanium (Ti). Bit line 6 is formed so as to connect to bit line contact plug 10A. Bit line 6 comprises a stack film of tungsten nitride (WN) and tungsten (W).

Third interlayer insulating film 21 is formed so as to cover bit line 6. Capacitance contact plugs 21A are formed so as to penetrate second interlayer insulating film 10 and third interlayer insulating film 21 and connect to respective substrate contact plugs 4A. Fourth interlayer insulating film 22 is formed on third interlayer insulating film 21. Capacitance section (capacitor element) 24 is formed so as to connect to capacitance contact plugs 21A.

Fifth interlayer insulating film 30, upper wiring layer 31 formed of aluminum (Al), copper (Cu), or the like, and surface protection film 32 are formed on capacitance section 24.

In the exemplary embodiment, first MOS transistor Tr1 comprises a trench gate electrode by way of example. However, first MOS transistor Tr1 may be, instead of a MOS transistor comprising a trench gate electrode, a planar MOS transistor or a recess channel type MOS transistor including a channel region on a side surface portions of a trench formed in a semiconductor substrate disclosed in Japanese Patent Laid-Open No. 2007-158269.

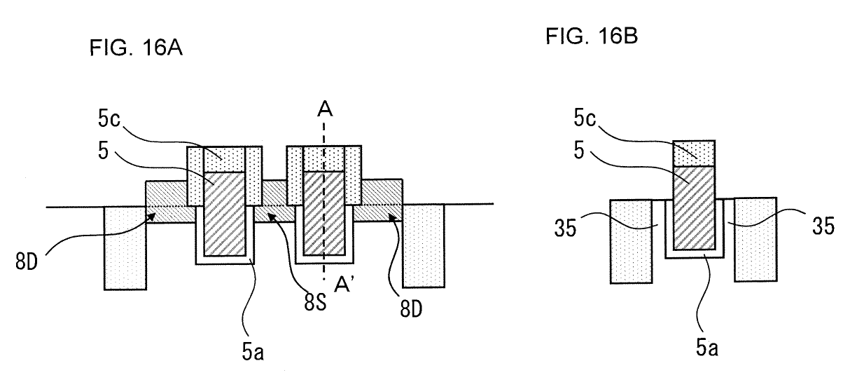

FIG. 16 is a diagram illustrating the operational state of a recess channel type first MOS transistor. As shown in FIG. 16B, in the MOS transistor, side portions made of semiconductor regions are formed in active region K so as to lie opposite the respective side surfaces of a gate electrode. When the MOS transistor is on, channel region 35 is formed at each of the side portions. That is, a channel current flows between first source region 8S and first drain region 8D via channel region 35.

Now, a peripheral circuit section will be described with reference to FIGS. 2 and 3B. As shown in FIG. 3B, planar MOS transistor Tr2 is provided in the peripheral circuit section. As shown in the sectional structure in FIG. 3B, second source region 108S and second drain region 108D are separately formed in active region K defined by isolation regions 3 in semiconductor substrate 1. Planar gate electrode 105 is formed between second source region 108S and second drain region 108D. Like gate electrode 5 in the above-described memory cell, gate electrode 105 is formed of a multilayer film of a polycrystalline silicon film and a metal film.

Furthermore, as shown in FIG. 3B, gate insulating film 5a is formed between gate electrode 105 and semiconductor substrate 1. Side walls 5b composed of an insulating film such as silicon nitride are formed on side surfaces of gate electrode 105. Insulating film 5c such as silicon nitride is formed on gate electrode 105.

Each of second source region 108S and second drain regions 108D comprises second impurity region 108a formed in semiconductor substrate 1 and silicon layer 109 formed on second impurity region 108a. Silicon layers 109 comprise third impurity regions 109a formed in lower layer portions in silicon layers 109 and fourth impurity layers 109b formed in upper layer portions in silicon layers 109. For example, as N-type impurities, phosphorous or arsenic is diffused in second, third, and fourth impurity regions 108a, 109a, and 109b. The amount of impurities in second impurity regions 108a is set to be larger than that of impurities in the first impurity regions of the memory cell section. The amount of impurities in third impurity regions 109a is set to be smaller than that of impurities in fourth impurity regions 109b. Furthermore, the first, the second, the third and the fourth impurity regions are same conductivity type. silicon layers 109 are formed by the selective epitaxial growth method.

As shown in FIG. 3B, first interlayer insulating film 4 and second interlayer insulating film 10 are formed on semiconductor substrate 1. Contact plugs 10B are formed so as to penetrate first interlayer insulating film 4 and second interlayer insulating film 10. Contact plugs 10B are formed by stacking tungsten (W) or the like on a barrier film such as TiN/Ti. Contact plugs 10B and bit line contact plug 10A in the memory cell section may be simultaneously formed.

First wiring layers 6B composed of the same wiring layer as that of bit lines 6 are formed so as to connect to respective contact plugs 10B. Each first wiring layer 6B is connected to upper wiring layer 31 via peripheral contact plug 22B.

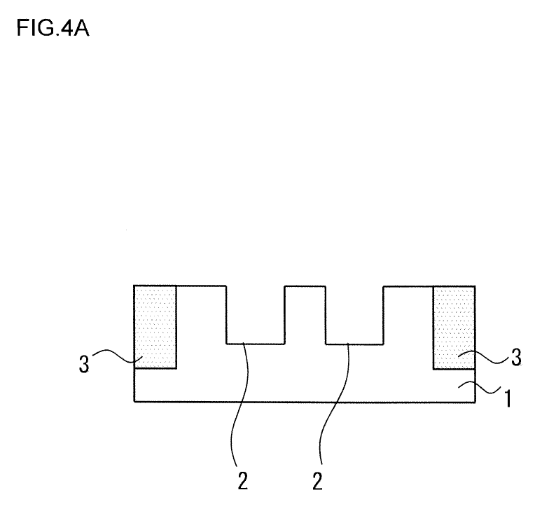

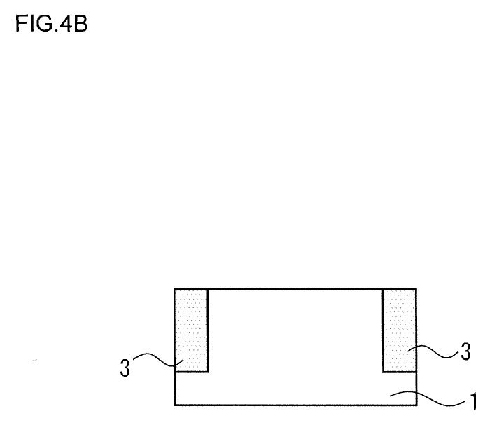

Now, a method for manufacturing a semiconductor device according to the exemplary embodiment will be described with reference to FIG. 4 to FIG. 12. FIG. 4 to FIG. 12 are diagrams illustrating the method for manufacturing the semiconductor device according to the exemplary embodiment. In each of the figures, A is a schematic sectional view of the memory cell section (FIG. 1) corresponding to line A-A′. B is a schematic sectional view of the peripheral circuit section (FIG. 2) corresponding to line B-B′. In the description below, unless otherwise specified, a process of manufacturing MOS transistor Tr1 for a memory cell and a process of manufacturing MOS transistor Tr2 for a peripheral circuit will be simultaneously described.

The memory cell section described below corresponds to a first active region, and the peripheral circuit section described below corresponds to a second active region.

As shown in FIGS. 4A and 4B, to define active region K in a principal surface of semiconductor substrate 1 composed of P-type silicon, an STI method is used to form isolation region 3 with an insulating film such as silicon oxide (SiO₂) embedded therein, in the entire principal surface except for active region K.

As shown in FIG. 4A, trench pattern 2 for gate electrodes is formed in the memory cell section. Trench pattern 2 is formed by etching the silicon in semiconductor substrate 1 through a photo resist (not shown in the drawings) as a mask.

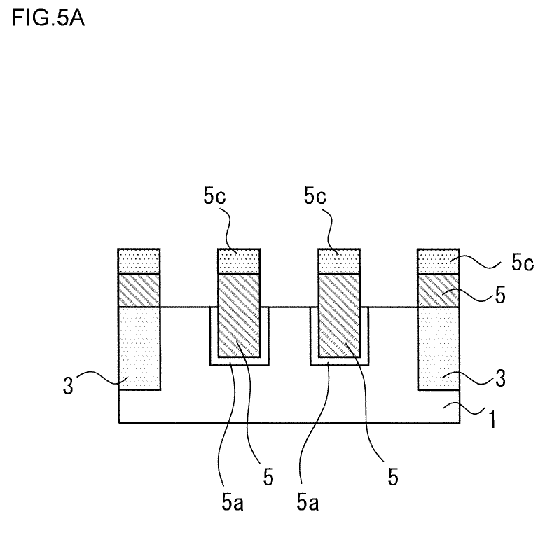

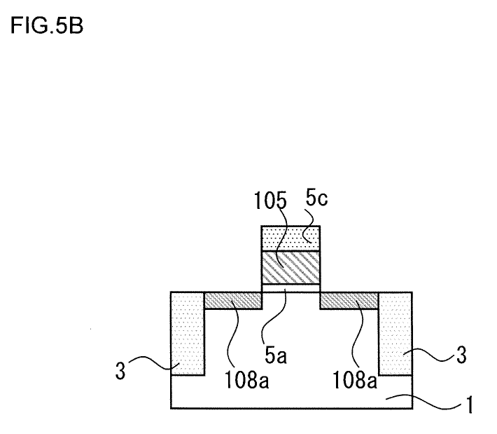

Then, as shown in FIGS. 5A and 5B, the silicon surface of semiconductor substrate 1 is oxidized into silicon oxide by a thermal oxidation method. Gate insulating films 5a of thickness about 4 nm are thus formed in a transistor formation region. The gate insulating film may be a stack film of silicon oxide and silicon nitride or a High-K film (high dielectric film). The “High-K film (high dielectric film)” refers to an insulating film having a larger relative dielectric constant than SiO₂ (the relative dielectric constant of SiO₂ is about 3.6), commonly used as gate insulating films in semiconductor devices. Typically, the relative dielectric constant of high dielectric film may be several tens to several thousand. Examples of the high dielectric film include HfSiO, HfSiON, HfZrSiO, HfZrSiON, ZrSiO, ZrSiON, HfAlO, HfAlON, HfZrAlO, HfZrAlON, ZrAlO, and ZrAlON.

The gate electrode may be formed of polysilicon. Alternatively, the gate electrode may be formed of a metal material as metal gate electrodes. In this case, the metal gate electrode may be composed of an alloy of one or more metal materials. For example, to form a metal gate electrode using an alloy, silicide may be used as a gate electrode material. Examples of the silicide include NiSi, Ni₂Si, Ni₃Si, NiSi₂, WSi₂, TiSi₂, VSi₂, CrSi₂, ZrSi₂, NbSi₂, MoSi₂, TaSi₂, CoSi, CoSi₂, PtSi, Pt₂Si, and Pd₂Si.

Thereafter, a polycrystalline silicon film containing N-type impurities is formed on each gate insulating film 5a by a CVD method using monosilane (SiH₄) and phosphine (PH₃) as material gas. In this case, the film thickness of the polycrystalline silicon film is set such that the interior of trench pattern 2 for gate electrodes is completely filled with the polycrystalline silicon film in the memory cell section. Alternatively, a polycrystalline silicon film containing no impurities such as phosphorous may be formed, and in the subsequent step, desired impurities may be doped into the polycrystalline silicon film by an ion implantation method.

Then, high-melting-point metal such as tungsten, tungsten nitride, or tungsten silicide is deposited, as a metal film, on the polycrystalline silicon film to a thickness of about 50 nm by a sputtering method. The polycrystalline silicon film and the metal film are formed into gate electrodes 5 and 105 via steps described below.

Insulating film 5c composed of silicon nitride is deposited on the metal film that is to form gate electrodes 5 and 105, to a thickness of about 70 nm by a plasma CVD method using monosilane and ammonia (NH₃) as material gas. Then, a resist (not shown in the drawings) is applied onto insulating film 5c. A photo resist pattern for formation of gate electrodes 5 and 105 is then formed through a mask for formation of gate electrodes 5 and 105 by a photolithography method.

Then, insulating film 5c is etched by anisotropic etching through the photo resist pattern as a mask. The photo resist pattern is removed. The metal film and the polycrystalline silicon film are etched through insulating film 5c as a hard mask to form gate electrodes 5 and 105.

Thereafter, the entire memory cell section is covered with a photo resist pattern. Phosphorous or arsenic (As) is ion-implanted into the exposed peripheral circuit section as N-type impurities to form second impurity regions 108a in the surface of the peripheral circuit section of semiconductor substrate 1. If for example, arsenic is used, ion implantation conditions may include an energy of 2 to 10 KeV and a dose of 1×10¹⁴ to 1×10¹⁵ atoms/cm².

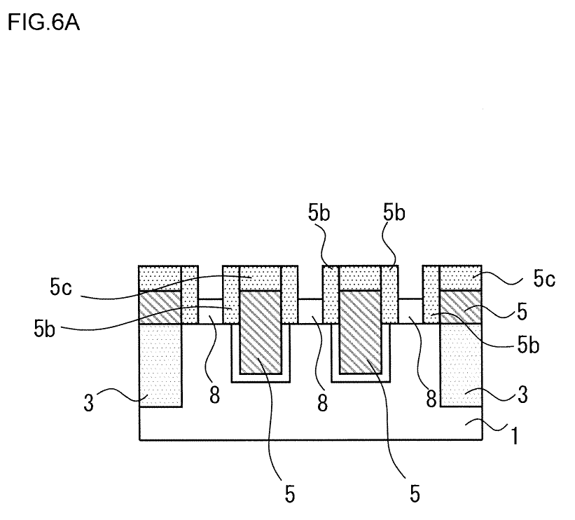

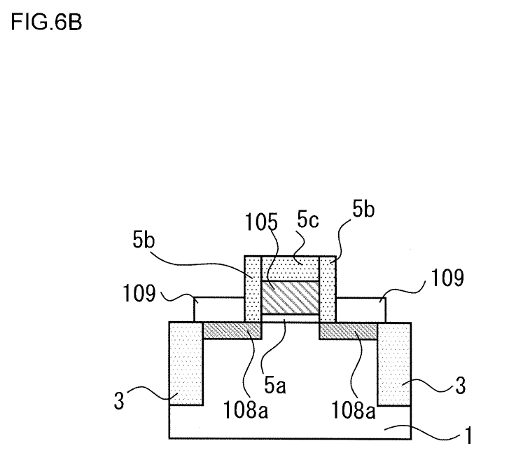

Then, as shown in FIGS. 6A and 6B, a silicon nitride film is deposited all over the surface of the resulting structure to a thickness of about 20 to 50 nm by the CVD method. The silicon nitride film is then etched back to form side walls 5b on side surfaces of gate electrodes 5 and 105.

Thereafter, with the clean silicon layer exposed from the surface of active region K formed in semiconductor substrate 1, silicon layers 8 and 109 of thickness about 30 to 50 nm are formed using the selective epitaxial growth method. An example of the selective epitaxial growth method is a selective CVD method using hydrogen chloride (HCl) and dichlorosilane (SiH₂Cl₂) as reaction gas in a high-temperature hydrogen (H₂) atmosphere at 800° C. Silicon layers 8 and 109 are formed on portions of active region K not covered with the gate electrodes. Silicon layers 8 and 109 are deposited on these portions, while slightly spreading in the lateral direction (FIGS. 1 and 2).

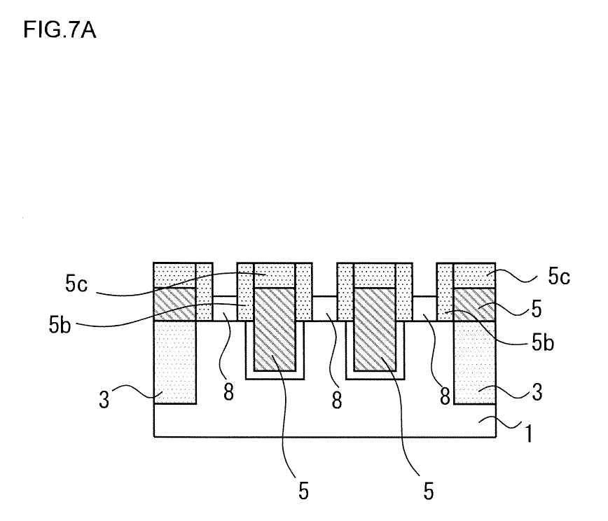

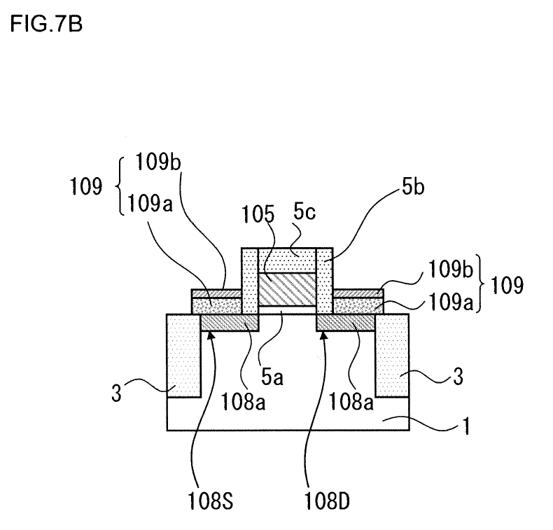

Then, as shown in FIGS. 7A and 7B, the memory cell section is covered with a photo resist pattern (not shown in the drawings). Arsenic or phosphorous (P) is ion-implanted into the exposed peripheral circuit section as N-type impurities to form third impurity regions 109a in the lower layer portions of silicon layers 109 formed in the peripheral circuit section. If for example, phosphorous is used, ion implantation conditions may include an energy of 10 to 25 KeV and a dose of 1×10¹³ to 5×10¹⁴ atoms/cm².

Subsequently, arsenic or phosphorous is ion-implanted into the upper layer portions of silicon layers 109 formed in the peripheral circuit section as N-type impurities to form fourth impurity regions 109b. If for example, arsenic is used, ion implantation conditions may include an energy of 10 to 20 KeV and a dose of 1×10¹⁵ to 6×10¹⁵ atoms/cm². The ion implantation energy is adjusted such that third impurity regions 109a form lower layers in silicon layers 109, whereas fourth impurity regions 109b form upper layers in silicon layers 109. Furthermore, the amount of impurities in third impurity regions 109a is set to be smaller than that of impurities in fourth impurity regions 109b. Moreover, the ion implantation energy is set such that second impurity regions 108a and fourth impurity regions 109b continue electrically with each other via third impurity regions 109a. This allows formation of second source region 108S and second drain region 108D of MOS transistor (Tr2) in the peripheral circuit section.

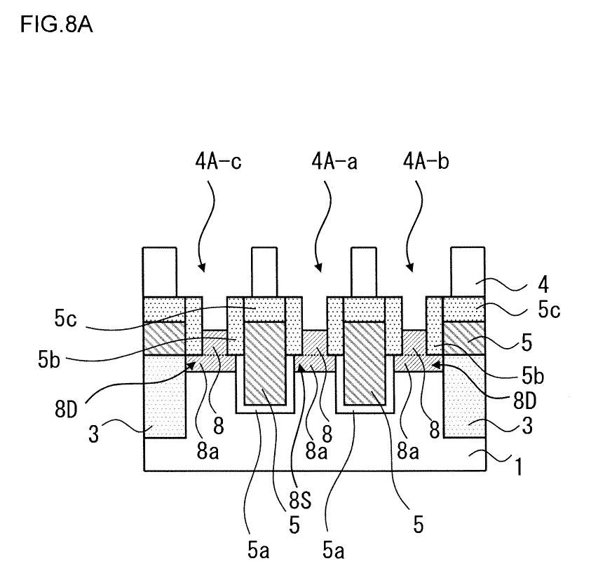

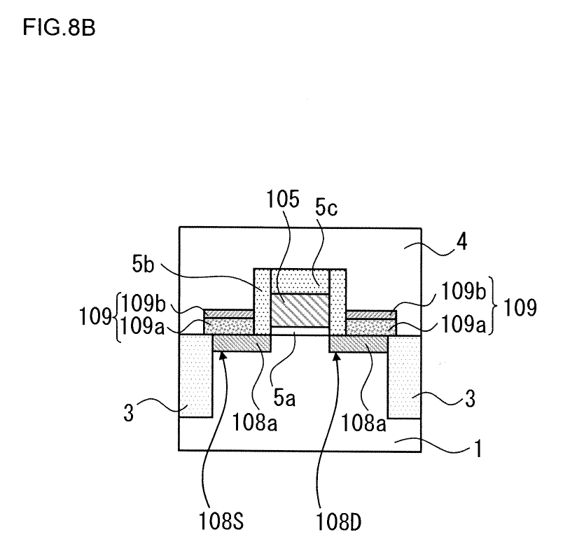

Then, as shown in FIGS. 8A and 8B, first interlayer insulating film 4 composed of silicon oxide is formed, by an LPCVD (Low Pressure CVD) method, to a thickness of, for example, about 600 nm so as to cover gate electrodes 5 and 105 and silicon layers 8 and 109. Thereafter, to allow recesses and protrusions associated with gate electrodes 5 and 105 to be flattened, first interlayer insulating film 4 is polished to a thickness of, for example, about 200 nm by the CMP method.

Thereafter, openings (contact holes) 4A-a, 4A-b, and 4A-c are formed at the positions of substrate contacts 205a, 205b, and 205c, respectively, in the memory cell section (FIG. 1) to partly expose the surface of silicon layers 8. A SAC (Self Aligned Contact) method can be used to form openings 4A-a, 4A-b, and 4A-c.

Thereafter, N-type impurities are ion-implanted via openings 4A-a, 4A-b, and 4A-c to form first impurity regions in the surfaces of silicon layers 8 and semiconductor substrate 1. If for example, phosphorous is used, ion implantation conditions may include an energy of 25 to 40 KeV and a dose of 1×10¹³ to 6×10¹³ atoms/cm². The amount of impurities in the first impurity regions is set to be smaller than that of impurities in second impurity regions 108a of the peripheral circuit section. A plurality of ion implantation operations with energy varied may be performed in order to form the first impurity regions both in silicon layers 8 and in the surface of semiconductor substrate 1. Furthermore, during a subsequent manufacturing step, in view of the adverse effect of thermal treatment, thermal diffusion from silicon layers 8 may be used to form the first impurity regions in the surface portion of semiconductor substrate 1. This allows formation of first source region 8S and first drain regions 8D of MOS transistor (Tr1) in the memory cell section.

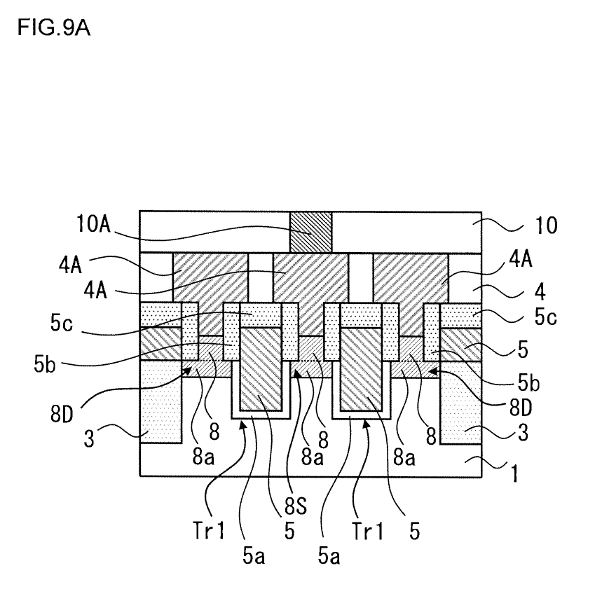

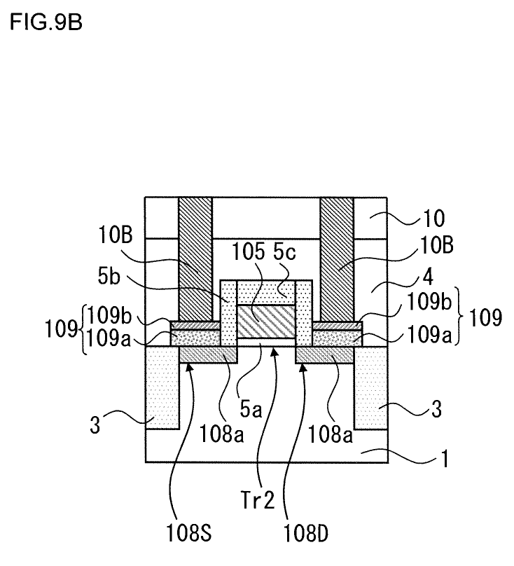

Then, as shown in FIGS. 9A and 9B, substrate contact plugs 4A are formed so as to fill openings 4A-a, 4A-b, and 4A-c. Substrate contact plugs 4A are formed by forming a polycrystalline silicon film with phosphorous doped therein all over the surface of the resulting structure and polishing the polycrystalline silicon film by the CMP method so as to exposed the surface of first interlayer insulating film 4.

Thereafter, second interlayer insulating film 10 composed of silicon oxide is formed, by, for example, the LPCVD method, to a thickness of, for example, about 200 nm so as to cover substrate contact plugs 4A and first interlayer insulating film 4.

Thereafter, openings are formed, and a film formed by stacking tungsten (W) on a barrier film such as TiN/Ti is filled into the openings to form bit line contact plug 10A and contact plugs 10B. Bit line contact plug 10A is connected to substrate contact plug 4A (the plug located in center 205a of the active region) in the memory cell section. Contact plugs 10B are connected silicon layers 109 in the peripheral circuit section. Contact plugs 10A and 10B may be formed simultaneously or during separate steps.

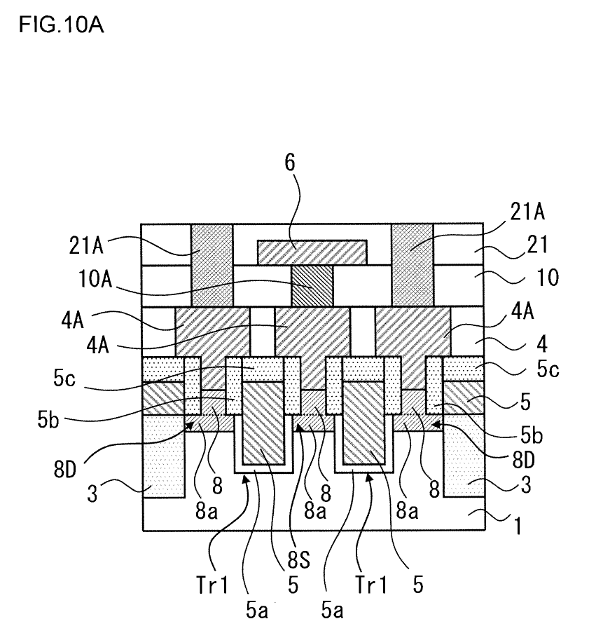

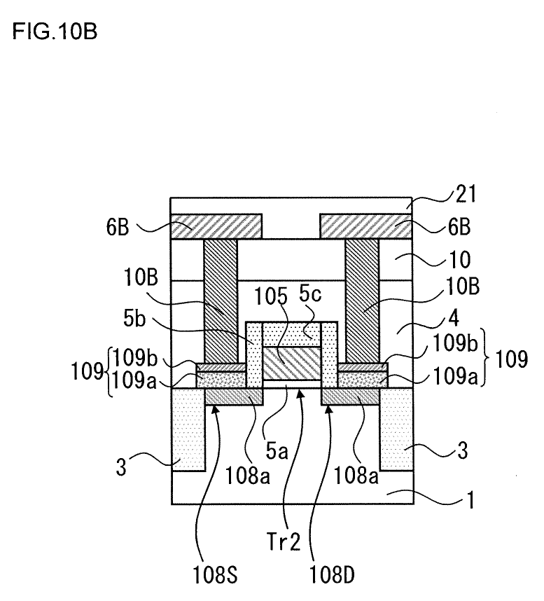

Then, as shown in FIGS. 10A and 10B, a stack film of tungsten nitride (WN) and tungsten (W) is stacked and patterned. Thus, on the memory cell section side, bit line 6 connected to bit line contact plug 10A is formed. At the same time, on the peripheral circuit section, wiring layers 6B connected to contact plugs 10B are formed. Then, third interlayer insulating film 21 is formed using silicon oxide or the like so as to cover bit line 6 and wiring layer 6B in the peripheral circuit section. Thereafter, capacitance contact plugs 21A connected to substrate contact plugs 4A (the plugs located at respective ends 205b and 205c of the active region) are formed in the memory cell section. Capacitance contact plugs 21A can be formed by filling the openings with a film obtained by stacking tungsten (W) on a barrier film such as TiN/Ti.

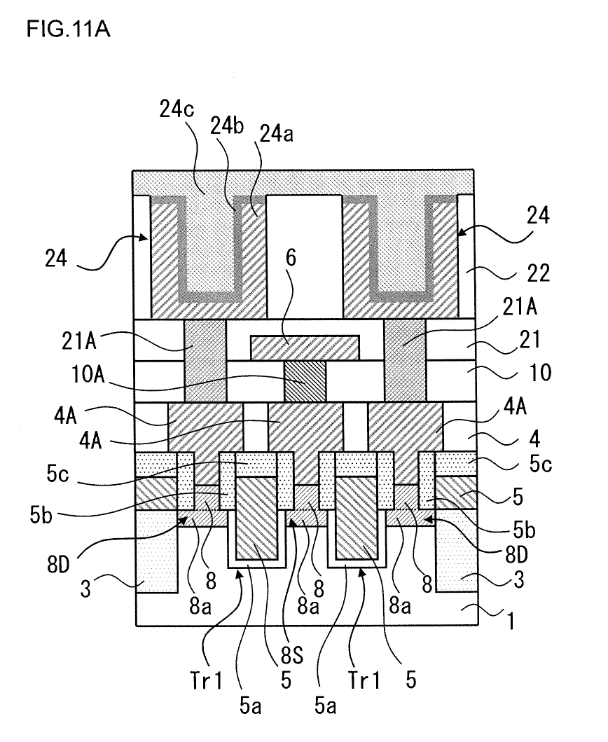

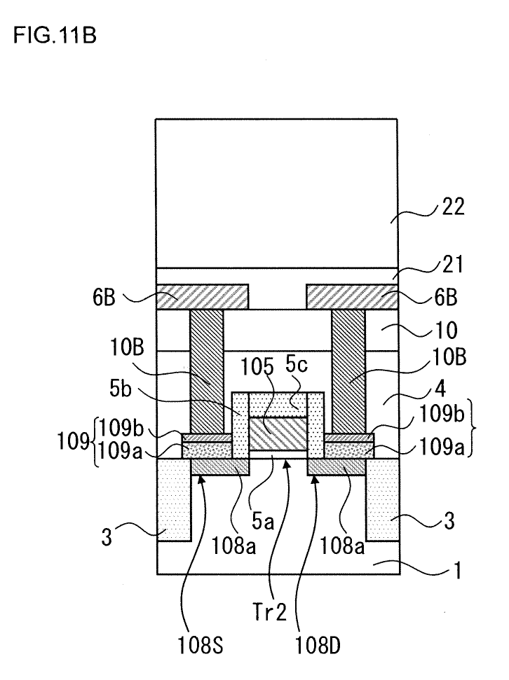

Then, as shown in FIGS. 11A and 11B, fourth interlayer insulating film 22 is formed using silicon oxide or the like. Thereafter, capacitance sections (capacitor elements) 24 are formed in the memory cell section. Each capacitance section 24 can be formed by sandwiching a high dielectric film such as hafnium oxide (HfO₂), zirconium oxide (ZrO₂), or aluminum oxide (Al₂O₃) between lower electrode 24a and upper electrode 24c both formed of titanium nitride (TiN) or the like.

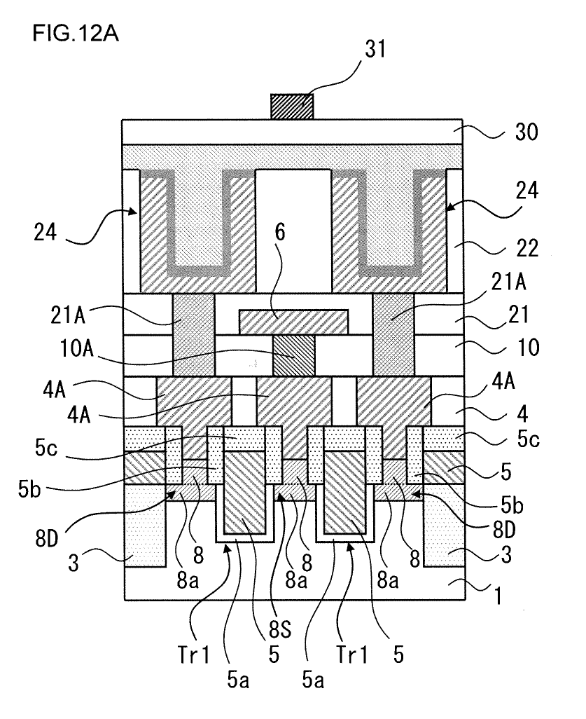

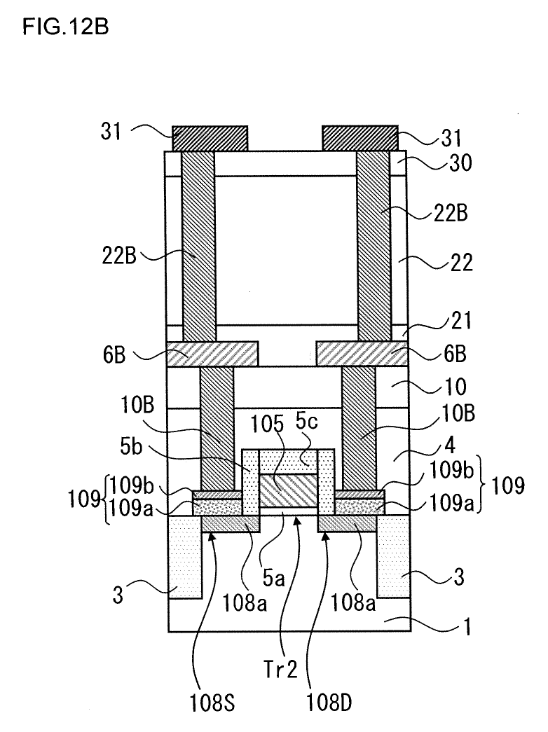

Then, as shown in FIGS. 12A and 12B, fifth interlayer insulating film 30 is formed using silicon oxide or the like. Thereafter, peripheral contact plugs 6B connected to wiring layers 6B are formed in the peripheral circuit section. Extraction contact plugs (not shown in the drawings) are formed in the memory cell section to apply an electrical potential to upper electrode 24c of capacitance section 24. Thereafter, upper wiring layer 31 is formed using aluminum (Al) or copper (Cu). Wiring layer 31 is connected to peripheral contact plugs 22B in the peripheral circuit section.

Thereafter, as shown in FIGS. 3A and 3B, a surface protection film is formed using silicon oxynitride (SiON) or the like, thus completing a DRAM element corresponding to a semiconductor device.

As described above, in the DRAM element corresponding to the semiconductor device according to the exemplary embodiment, in the first circuit region (corresponding to the memory cell section), the first impurity regions in the first source/drain regions of the first MOS transistor can be set to have a sufficiently low concentration. As a result, the first and the second impurity regions are same conductivity type, and the amount of impurities in the first impurity regions can be set to be smaller than that of impurities in the second impurity regions. In this manner, in the first MOS transistor in the first circuit region, the amount of impurities in the first impurity regions in the first source/drain regions is small. Thus, in the off state, a possible leakage current from a PN junction in the first source/drain regions can be inhibited. Furthermore, the bottom portions of the first impurity regions are located at shallow positions with respect to the surface of the semiconductor substrate. This serves to reduce the amount of impurities. Thus, the impurities can be prevented from spreading as a result of thermal diffusion, and a possible short channel effect can be inhibited.

In the second circuit region (corresponding to the peripheral circuit section), third impurity regions 109a are formed below fourth impurity regions 109b provided in the upper layer portions of raised silicon layers 8 and having a large amount of impurities, third impurity regions 109a containing a smaller amount of impurities than fourth impurity regions 109b. Thus, the high-concentration impurities can be prevented from spreading as a result of thermal diffusion, and a possible short channel effect can be inhibited. Consequently, a threshold voltage can be easily set to a desired value. Therefore, as described above, by setting the threshold voltage for the second MOS transistor to be lower than that for the first MOS transistor in the first circuit region, the drain current can be easily increased in the on state. This also prevents the short channel inhibiting effect from excessively reducing the threshold voltage to affect circuit operations.

Furthermore, second, third, and fourth impurity regions 108a, 109a, and 109b functioning as the second source/drain regions of the second MOS transistor are same conductivity type and electrically continuous. No region of silicon layers 8 is doped with impurities. Thus, even with the flow of a large on current, the characteristics of the device can be inhibited from being degraded as a result of hot carriers. Furthermore, the planar second MOS transistor in the second circuit region allows a parasitic capacitance in the gate electrode to be reduced compared to a MOS transistor with a trench gate electrode. Consequently, a circuit suitable for an increase in speed can be provided.

As described above, with the DRAM element formed by the application of the present invention, a high-performance DRAM can be easily manufactured which offers excellent data holding characteristics (refresh characteristics), quick responsiveness, and long-lasting reliability.

The present invention is thus applied to the DRAM element. Furthermore, the threshold voltage for the first MOS transistors located in the first circuit region (corresponding to the memory cell section) is set to be higher than that for the second MOS transistors located in the second circuit region (corresponding to the peripheral circuit section). As described above, in the first MOS transistor, the amount of impurities in the first impurity regions are small. This allows a possible leakage current and a possible short channel effect to be inhibited. Thus, a higher threshold voltage can be easily set, eliminating the need to increase the amount of impurities to be doped into the channel region for control of the threshold voltage. This enables a possible leakage current from the PN junction in the first source/drain regions to be further inhibited. Furthermore, setting a higher threshold voltage allows a possible channel current to be inhibited in the off state. Thus, in the first MOS transistor in the first circuit region, not only the leakage current from the first source/drain regions but also the channel current can be reduced in the off state. A first MOS transistor with the off current reduced by this synergetic effect can be easily formed.

### Second Exemplary Embodiment

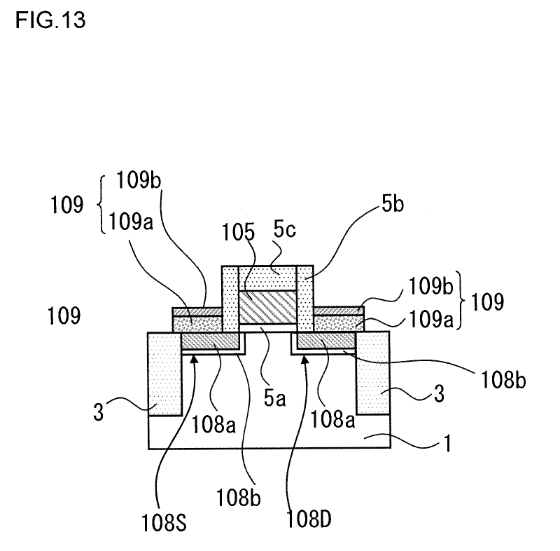

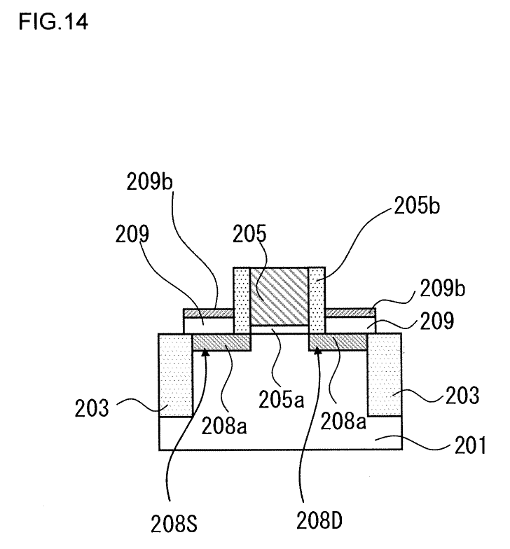

Another exemplary embodiment of the present invention will be described with reference to FIG. 13 (corresponding to a section of the peripheral circuit section taken along line B-B′).

After forming structure illustrated in FIG. 5 in the first exemplary embodiment, fifth impurity regions 108b of the same conductivity type (P type) as that of semiconductor substrate 1 are formed by the ion implantation method so as to surround the outside of respective second impurity region 108a in the peripheral circuit section of semiconductor substrate 1. The conductivity type of the fifth impurity regions is different from the conductivity type of the first, the second, the third, and the fourth impurity regions. If for example, boron (B) is used, the ion implantation conditions may include an energy of 10 to 20 KeV and a dose of 1×10¹³ to 8×10¹³ atoms/cm². In the exemplary embodiment, the dose is set to be higher than the P-type impurity concentration of semiconductor substrate 1.

Fifth impurity regions 108b function as pocket implantation regions for the second source/drain regions of second MOS transistor (Tr2). Thereafter, steps similar to those of the first exemplary embodiment are performed to complete a semiconductor device.

In the exemplary embodiment, fifth impurity regions 108b of the opposite conductivity type are formed in the second source/drain regions of second MOS transistor (Tr2). This is effective for preventing second impurity regions 108a from spreading in the lateral direction as a result of thermal diffusion. Thus, a possible short channel effect can further be inhibited from being exerted on the MOS transistors in the peripheral circuit section (second circuit region). Formation of fifth impurity regions 108b does not affect the structure of second, third and fourth impurity regions (108a, 109a, and 109b). Consequently, a possible short channel effect can further be inhibited from being exerted on the MOS transistors in the peripheral circuit section, with the characteristics of the transistors effectively prevented from being degraded as a result of hot carriers.

Even with miniaturization further increased, the significant short-channel inhibiting effect of the exemplary embodiment allows the threshold voltage for the MOS transistors in the peripheral circuit section to be easily set to a smaller value for the optimum operation.

In the above-described exemplary embodiment, N channel type MOS transistors are formed in both the first and second circuit regions. However, P channel type MOS transistors may be formed by changing the conductivity type of the impurities implanted in the first to fourth impurity regions to P, while changing the conductivity type of the impurities implanted in the fifth impurity regions to N.

In the above-described first and second exemplary embodiments, the semiconductor device comprises the DRAM element. However, the present invention is not limited to the semiconductor device comprising the DRAM element. The present invention is applicable to a semiconductor device comprising a first circuit region in which MOS transistors with a possible leakage current inhibited in the off state are arranged and a second circuit region in which MOS transistors with a large drain current flowing therethrough in the on state are arranged, the first and second circuit regions being formed on one semiconductor chip.

It is apparent that the present invention is not limited to the above embodiments, but may be modified and changed without departing from the scope and spirit of the invention.

What is claimed is:

1. A semiconductor device comprising a semiconductor substrate, a first circuit region and a second circuit region,
wherein the first circuit region comprises:
a first MOS transistor comprising, as first impurity regions, a pair of first source/drain regions including first portions formed in the semiconductor substrate and second portions formed on the first portions so as to project from the semiconductor substrate,
the second circuit region comprises:
a second MOS transistor comprising a pair of second source/drain regions including second impurity regions formed in the semiconductor substrate, third impurity regions formed so as to be in contact with the second impurity regions and to extend upward from the semiconductor substrate, and fourth impurity regions formed on the third impurity regions,
the first, the second, the third and the fourth impurity regions are same conductivity type,
the amount of impurity in the third impurity regions is smaller than the amount of impurity in the fourth impurity regions, and
the amount of impurity in the first impurity regions is smaller than the amount of impurity in the second impurity regions.

2. A semiconductor device comprising:
a semiconductor substrate;
a first circuit region comprising a first MOS transistor including a pair of first source/drain regions with first impurity regions; and
a second circuit region comprising a second MOS transistor including a pair of second source/drain regions, the second source/drain regions including second impurity regions as a bottom layer, third impurity regions disposed on the second impurity regions, and fourth impurity regions disposed on the third impurity regions,
wherein the first impurity regions comprise first portions formed immediately beneath a surface of the semiconductor substrate and second portions formed on the first portions so as to project from the surface of the semiconductor substrate,
the second impurity regions are formed in the semiconductor substrate,
the third and fourth impurity regions are formed so as to project from the surface of the semiconductor substrate,
the first, the second, the third and the fourth impurity regions are same conductivity type,
the amount of impurity in the third impurity regions is smaller than the amount of impurity in the fourth impurity regions,
the amount of impurity in the first impurity regions is smaller than the amount of impurity in the second impurity regions, and
a threshold voltage of the first MOS transistor is larger than a threshold voltage of the second MOS transistor.

3. The semiconductor device according to claim 1, wherein the amount of impurity doped in the first impurity regions is 1×10¹³ to 6×10¹³ atoms/cm².

4. The semiconductor device according to claim 1, wherein the first circuit region further comprises a memory cell including a capacitor connected to one of the first source/drain regions,
the first circuit region forms a memory cell region, and
the semiconductor device forms a DRAM (Dynamic Random Access Memory).

5. The semiconductor device according to claim 1, wherein the first MOS transistor comprises a trench gate electrode or a recess type gate electrode forming channel on side surface portions of a trench, and
the second MOS transistor comprises a planar gate electrode.

6. The semiconductor device according to claim 1, wherein the amount of impurity doped in the second impurity regions is 1×10¹⁴ to 1×10¹⁵ atoms/cm².

7. The semiconductor device according to claim 1, wherein the amount of impurity doped in the third impurity regions is 1×10¹³ to 5×10¹⁴ atoms/cm².

8. The semiconductor device according to claim 1, wherein the amount of impurity doped in the fourth impurity regions is 1×10¹⁵ to 6×10¹⁵ atoms/cm².

9. The semiconductor device according to claim 1, wherein the second source/drain regions further comprise a pair of fifth impurity regions formed in the semiconductor substrate so that each fifth impurity region covers a periphery of each second impurity region, a conductivity type of the fifth impurity regions being different from a conductivity type of the second impurity regions.

10. The semiconductor device according to claim 9, wherein the amount of impurity doped in the fifth impurity regions is 1×10¹³ to 8×10¹³ atoms/cm².

11. The semiconductor device according to claim 2, wherein the semiconductor device further comprises:
a first interlayer insulating film on the semiconductor substrate, the first MOS transistor and the second MOS transistor being covered with the first interlayer insulating film;
a second interlayer insulating film on the first interlayer insulating film;
a first contact plug penetrating the first interlayer insulating film and connected to the second portion of one of the first source/drain regions of the first MOS transistor;
a second contact plug penetrating the second interlayer insulating film and connected to the first contact plug;
a third contact plug penetrating the first and the second interlayer insulating films and connected to the fourth impurity region of one of the second source/drain regions of the second MOS transistor;
a first wiring layer on the second interlayer insulating film in the first circuit region, the first wiring layer being directly connected to the second contact plug; and
a second wiring layer on the second interlayer insulating film in the second circuit region, the second wiring layer being directly connected to the third contact plug.

12. The semiconductor device according to claim 11, wherein a part of a gate electrode of the first MOS transistor is disposed under the surface of the semiconductor substrate, the gate electrode of the first MOS transistor being covered by the first interlayer insulating film, and
a gate electrode of the second MOS transistor is disposed over the surface of the semiconductor substrate, the gate electrode of the second MOS transistor being covered by the first interlayer insulating film.

13. A method for manufacturing a semiconductor device, the method comprising:
preparing a semiconductor substrate comprising a first active region and a second active region;
forming gate insulating films and gate electrodes in the first and second active regions, respectively;
implanting first conductive type impurity into portions of the second active region arranged opposite each other across the gate electrode in the semiconductor substrate to form a pair of second impurity regions;
forming semiconductor layers on portions of the first active region arranged opposite each other across the gate electrode in the semiconductor substrate and on the second impurity regions in the second active region, the semiconductor layers projecting upward from the semiconductor substrate;
implanting first conductive type impurity into lower portions of the semiconductor layers on the second impurity regions to form a pair of third impurity regions in contact with the second impurity regions;
implanting first conductive type impurity into upper portions of the semiconductor layers on the second impurity regions to form a pair of fourth impurity regions in contact with the third impurity regions, whereby forming a second MOS transistor, an impurity concentration of the third impurity regions being smaller than an impurity concentration of the fourth impurity regions; and
implanting first conductive type impurity into portions of the first active region arranged opposite each other across the gate electrode in the semiconductor substrate and into the semiconductor layers on the portions of the first active region to form a pair of first impurity regions, whereby forming a first MOS transistor, an impurity concentration of the first impurity regions being smaller than an impurity concentration of the second impurity regions.

14. The method for manufacturing the semiconductor device according to claim 13, wherein in implanting first conductive type impurity into the portions of the first active region and the semiconductor layers in the first active region to from the pair of first impurity regions,
phosphorus (P) is implanted as the first conductive type impurity under conditions of a dose of 1×10¹³ to 6×10¹³ atoms/cm².

15. The method for manufacturing the semiconductor device according to claim 13, wherein in implanting first conductive type impurity into the portions of the second active region to form the pair of second impurity regions,
arsenic (As) is implanted as the first conductive type impurity under conditions of a dose of 1×10¹⁴ to 1×10¹⁵ atoms/cm².

16. The method for manufacturing the semiconductor device according to claim 13, wherein in implanting first conductive type impurity into the lower portions of the semiconductor layers on the second impurity regions to form the pair of third impurity regions,
phosphorous (P) is implanted as the first conductive type impurity under conditions of a dose of 1×10¹³ to 5×10¹⁴ atoms/cm².

17. The method for manufacturing the semiconductor device according to claim 13, wherein in implanting first conductive type impurity into the upper portions of the semiconductor layers on the second impurity regions to form the pair of fourth impurity regions,
arsenic (As) is implanted as the first conductive type impurity under conditions of a dose of 1×10¹⁵ to 6×10¹⁵ atoms/cm².

18. The method for manufacturing the semiconductor device according to claim 13, further comprising, after implanting first conductive type impurity into the portions of the first active region and the semiconductor layers in the first active region to from the pair of first impurity regions,
forming a capacitor connected to one of the first impurity regions of the first MOS transistor; and
forming a bit line connected to the other of the first impurity regions of the first MOS transistor,
wherein a DRAM (Dynamic Random Access Memory) is formed as the semiconductor device.

19. The method for manufacturing the semiconductor device according to claim 13, further comprising, between implanting first conductive type impurity into the portions of the second active region to form the pair of second impurity regions and forming the semiconductor layers,
implanting second conductive type impurity into portions of the second active region arranged opposite each other across the gate electrode in the semiconductor substrate to form a pair of fifth impurity regions such that each fifth impurity region covers a periphery of each second impurity region.

20. The method for manufacturing the semiconductor device according to claim 19, wherein in implanting second conductive type impurity into the portions of the second active region to form the pair of fifth impurity regions,
boron (B) is implanted as the second conductive type impurity under conditions of a dose of 1×10¹³ to 8×10¹³ atoms/cm².
